(19) United States
(12) Patent Application Publication
(10) Pub. No.: US 2020/0313017 A1
(43) Pub. Date: Oct. 1, 2020

(54) SOLAR CELL MODULE AND SOLAR CELL SYSTEM

(71) Applicant: Panasonic Corporation, Kadoma-shi (JP)

(72) Inventor: Shin Nanba, Osaka (JP)

(73) Assignee: Panasonic Corporation, Kadoma-shi (JP)

(21) Appl. No.: 16/829,532

(22) Filed: Mar. 25, 2020

(30) Foreign Application Priority Data
Mar. 29, 2019 (JP) 2019-068091

(51) Int. Cl. H01L 31/05; H01L 31/02; H01L 31/044; H01L 31/048; H01L 31/18; H02S 40/34

(52) U.S. Cl. CPC H01L 31/0504; H01L 31/02008; H02S 40/34; H01L 31/048; H01L 31/18; H01L 31/044

(57) ABSTRACT

A solar cell module includes a first solar cell subgroup including two first solar cell strings connected in series, a second solar cell subgroup including two second solar cell strings connected in series, a first bypass diode connected in parallel to the first solar cell subgroup, a second bypass diode connected in parallel to the second solar cell subgroup, a pair of first external wires, and a pair of second external wires. A first portion on a high-potential side of a low-potential side first solar cell string having lower potential out of the two first solar cell strings and a second portion on a high-potential side of a low-potential side second solar cell string having lower potential out of the two second solar cell strings are electrically connected to each other.

### CROSS REFERENCE TO RELATED APPLICATION

The entire disclosure of Japanese Patent Application No. 2019-068091 filed on Mar. 29, 2019, including the specification, claims, drawings, and abstract is incorporated herein by reference in its entirety.

### TECHNICAL FIELD

The present disclosure generally relates to a solar cell module. The present disclosure generally relates to a solar cell system including a plurality of solar cell modules that are electrically connected to one another.

### BACKGROUND

An example of a conventional solar cell module disclosed in JP 2019-024070 A is known. This solar cell module includes two solar cell strings that are connected in series, and a bypass diode that is connected in parallel to the two solar cell strings connected in series, and each of the solar cell strings includes a plurality of solar cells that are connected in series. When light-shielding objects such as fallen leaves cover particular solar cells included in the two solar cell strings, an amount of power generation of the particular solar cells is decreased, which may cause heat generation. When the bypass diode is provided, the above-described two solar cell strings including the solar cells in which the amount of power generation is decreased are short-circuited by the bypass diode. Therefore, substantially no current flows through the two solar cell strings, which can suppress damage to the solar cell and the solar cell module due to heat generation.

### SUMMARY

### Technical Problem

Providing a number of bypass diodes in the solar cell module makes it possible not only to suppress damage to the solar cell and the solar cell module due to heat generation, but also to suppress reduction in output even when the light-shielding objects cover particular solar cells, thereby easily maintaining a high output. However, providing a number of bypass diodes easily causes an increase in size of the solar cell and an increase in manufacturing cost.

It is an advantage of the present disclosure to provide a solar cell module that can easily maintain a high output with a simple configuration, and a solar cell system.

### Solution to Problem

To solve the problems described above, a solar cell module of the present disclosure includes a first solar cell subgroup including two first solar cell strings connected in series, in which each of the first solar cell strings includes a plurality of solar cells, a second solar cell subgroup including two second solar cell strings connected in series, in which each of the second solar cell strings includes a plurality of solar cells, a first bypass diode part that is connected in parallel to the first solar cell subgroup and includes one first bypass diode or a plurality of first bypass diodes connected in series, a second bypass diode part that is connected in parallel to the second solar cell subgroup and includes one second bypass diode or a plurality of second bypass diodes connected in series, a pair of first external wires used to supply electric power to outside, and a pair of second external wires used to supply electric power to the outside, wherein a first portion having the highest potential, in a low-potential side first solar cell string having lower potential out of the two first solar cell strings, and a second portion having the highest potential, in a low-potential side second solar cell string having lower potential out of the two second solar cell strings, are electrically connected to each other.

### Advantageous Effects of Invention

The solar cell module and system according to the present disclosure can easily maintain a high output with a simple configuration.

### BRIEF DESCRIPTION OF DRAWINGS

The figures depict one or more implementations in accordance with the present teaching, by way of example only, not by way of limitations. In the figures, like reference numerals refer to the same or similar elements.

Embodiments of the present disclosure will be described based on the following figures, wherein:

FIG. 1 is a plan view illustrating a solar cell module of an embodiment of the present disclosure viewed from a light receiving side;

FIG. 2 is a plan view illustrating the solar cell module viewed from a rear side;

FIG. 3 is a cross sectional plan view taken along line A-A of FIG. 1;

FIG. 4 is a plan view illustrating an actual solar cell module of the present disclosure including a number of solar cells viewed from the light receiving side;

FIG. 5 illustrates an equivalent circuit of FIG. 1 representing the solar cell module using simplified diagrams;

FIG. 6A is a diagram illustrating a structure represented in the simplified diagram;

FIG. 6B is a diagram illustrating a bypass diode;

FIG. 7 is a diagram representing a solar cell module of a known square cell type using the simplified diagrams;

FIG. 8 is a diagram representing a solar cell module of a known square cell type using the simplified diagrams;

FIG. 9A is a diagram illustrating a structure of a conventional solar cell module 1 to be subjected to the simulation, the results of which are shown in FIG. 10, FIG. 11, and FIG. 12;

FIG. 9B is a diagram illustrating a structure of a conventional solar cell module 2 to be subjected to the simulation, the results of which are shown in FIG. 10, FIG. 11, and FIG. 12;

FIG. 9C is a diagram illustrating a structure of a solar cell module of the present disclosure to be subjected to the simulation, the results of which are shown in FIG. 10, FIG. 11, and FIG. 12;

FIG. 10 is a graph showing a simulation result of a module output regarding each of three types of solar cell modules illustrated in FIG. 9A, FIG. 9B, and FIG. 9C respectively;

FIG. 11 is a graph showing a simulation result of a value of a current flowing in a solar cell module which is assumed to be covered with light-shielding objects, regarding each of three types of solar cell modules illustrated in FIG. 9A, FIG. 9B, and FIG. 9C respectively;

FIG. 12 is a graph showing a simulation result of a value of a current flowing in a bypass diode, regarding each of three types of solar cell modules illustrated in FIG. 9A, FIG. 9B, and FIG. 9C respectively;

FIG. 13 is a diagram representing a solar cell module of a modification using the simplified diagrams;

FIG. 14 is a diagram representing, using the simplified diagrams, a solar cell module which is the same as in FIG. 9C except that no external wires are connected;

FIG. 15 is a diagram representing a solar cell module of other modification, using the simplified diagrams;

FIG. 16 is a diagram representing a solar cell module of another modification, using the simplified diagrams;

FIG. 17 is a diagram representing a solar cell module of further modification, using the simplified diagrams;

FIG. 18 is a diagram representing a solar cell module of a known strip type, using the simplified diagrams;

FIG. 19 is a plan view corresponding to FIG. 2 in a solar cell module of a modification having four terminal boxes;

FIG. 20 is a schematic diagram illustrating an installation position of a terminal box which is adaptable in the solar cell module of the present disclosure;

FIG. 21 is a schematic diagram illustrating an installation position of another terminal box which is adaptable in the solar cell module of the present disclosure;

FIG. 22A is a schematic diagram illustrating a structure of the solar cell system of the present disclosure; and

FIG. 22B is a schematic diagram illustrating a structure of the solar cell system of the present disclosure.

### DESCRIPTION OF EMBODIMENTS

Hereinafter, embodiments according to the present disclosure will be described with reference to the accompanying drawings. It is originally assumed that, when a plurality of embodiments, modifications and the like are included below, their characteristics parts are appropriately combined to construct a new embodiment. In the examples below, the same reference numeral will be given to the same components in the drawings, and duplicated description will be omitted. A plurality of drawings include schematic diagrams, and dimensional ratios among length, width and height of each member are not necessarily the same among different diagrams. In addition, among the components described below, components not recited in any of the independent claims defining the most generic part of the concept of the present disclosure are optional components but are not essential components. A solar cell module of the present disclosure may be formed in a curved plate shape, but a case will be described below as an example where the solar cell module is formed in a flat plate shape.

In the following description, in the solar cell module, a side on which sunlight is mainly incident (over 50% to 100%) is referred to as a light receiving side (front side), and a side opposite to the front side is referred to as a rear side. In the following description and in the description of the drawings, a direction X indicates an extending direction of a string described below, and a direction Y indicates an alignment direction of the strings that are disposed in a plurality of columns. A direction Z indicates a thickness direction of the solar cell module. The directions X, Y, and Z are orthogonal to one another. The solar cell module of the present disclosure may be configured by electrically connecting the same two structures (the same two solar cell submodules), and a pair of external wires may protrude from each structure (each solar cell submodule), the pair of external wires including a high potential external wire and a low potential external wire having a potential lower than the high potential external wire.

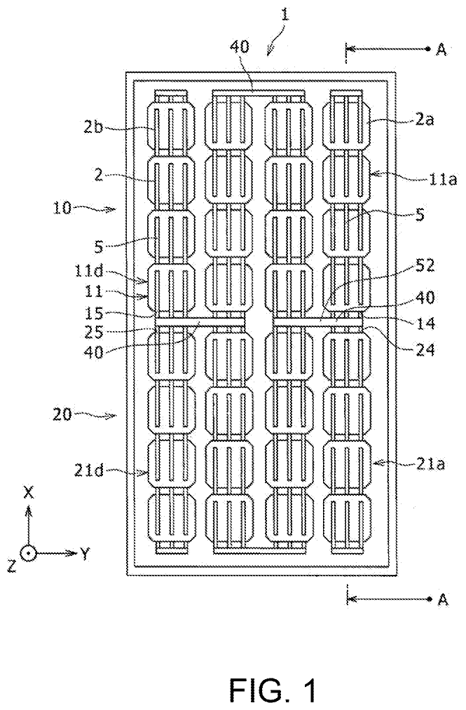

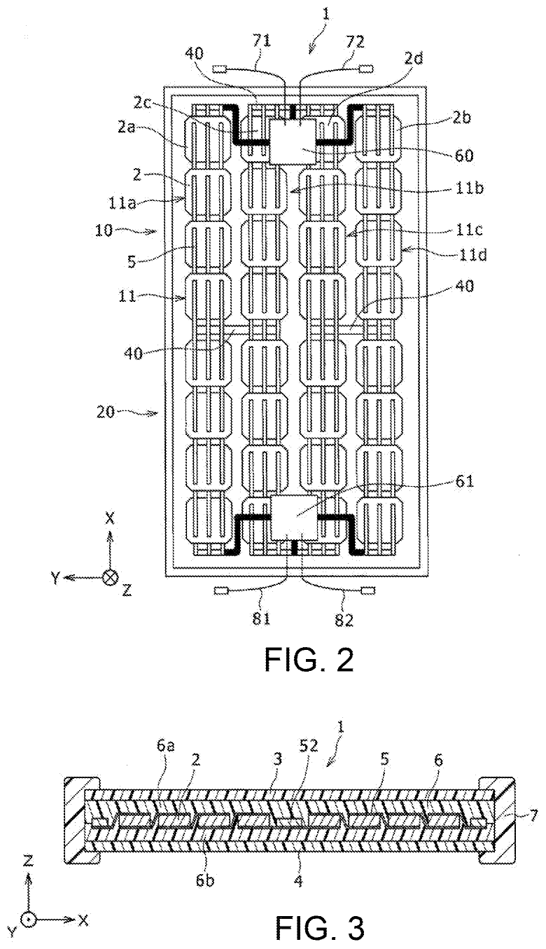

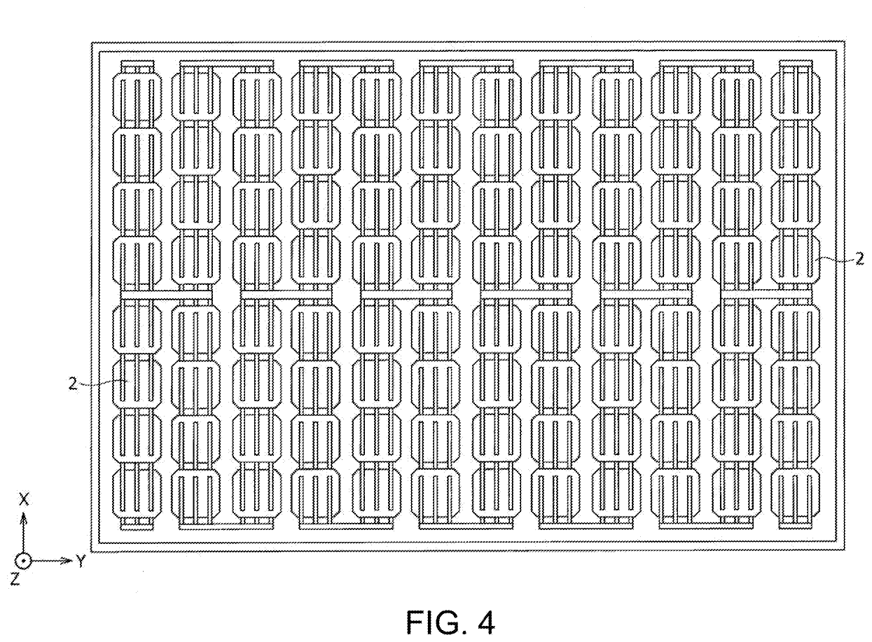

FIG. 1 is a plan view illustrating a solar cell module 1 of an embodiment of the present disclosure viewed from a light receiving side, and FIG. 2 is a plan view illustrating the solar cell module 1 viewed from the rear side. FIG. 2 is a diagram including an internal structure when the solar cell module 1 is viewed from the rear side. FIG. 3 is a cross sectional plan view taken along line A-A of FIG. 1. Note that the solar cell module actually includes a number of solar cells 2 in many cases, as illustrated in FIG. 4 that is a plan view illustrating the solar cell module viewed from the light receiving side. However, to make it easy to understand the essence of the technique disclosed here and to make the drawings easier to see, all of the embodiments and modification are described using solar cell modules 1, 301, 401, 501, 601, 801, and 901 in which the number of solar cells 2 is relatively small.

As illustrated in FIG. 1, the solar cell module 1 has a flat plate structure formed in a substantially rectangular shape in plan view. As illustrated in FIG. 2, the solar cell module 1 includes a first terminal box 60 on one side in a longitudinal direction (direction X) of the rectangular shape and on the rear side, and a second terminal box 61 on the other side in the direction X and on the rear side. In addition, as illustrated in FIG. 3, the solar cell module 1 includes a plurality of solar cells 2, a front side substrate 3, a rear side substrate 4, wiring members 5, a sealing member 6, and a frame 7.

The solar cell 2 is comprised of, for example, a crystalline semiconductor made of monocrystalline silicon, polycrystalline silicon or the like. The solar cell 2 includes, for example, an n-type region and a p-type region, and a junction to form an electric field for isolating carriers is provided at an interface between the n-type region and the p-type region. An upper surface of the solar cell 2 is formed in a substantially square shape, but is not limited thereto. The solar cell 2 to be used may have any known structure or any shape.

The front side substrate 3 is provided on the light receiving side of the plurality of solar cells 2 on which light is mainly incident, to thereby protect the front side of the solar cell module 1. The front side substrate 3 is made of a material having transparency, and is made of, for example, a transparent plastic or glass having transparency. The front side substrate 3 may be comprised of a transparent resin substrate, or may be made of a transparent resin, but in this case, the resin substrate may be made of at least one type of resin selected, for example, from polycarbonate (PC), polyethylene (PE), polypropylene (PP), cyclic polyolefin, polymethyl methacrylate (PMMA), polytetrafluoroethylene (PTFE), polystyrene (PS), polyethylene terephthalate (PET), and polyethylene naphthalate (PEN). The polycarbonate has excellent impact resistance and transparency. The front side substrate 3 is particularly a resin substrate made of polycarbonate as its main component, and may be, for example, a substrate whose polycarbonate content is 90 wt % or more, or 95 wt % to 100 wt %.

The rear side substrate 4 may be made of a material having transparency or may be made of an opaque material. When the rear side substrate 4 is made of a material having transparency, the rear side substrate 4 may be comprised of, for example, glass or a transparent resin substrate. The rear side substrate 4 may be comprised of an opaque resin substrate when the solar cell module 1 is not assumed to receive light from a rear surface side. The rear side substrate 4 may be made of at least one type selected, for example, from cyclic polyolefin, polycarbonate (PC), polymethyl methacrylate (PMMA), polyether ether ketone (PEEK), polystyrene (PS), polyethylene terephthalate (PET), and polyethylene naphthalate (PEN). Alternatively, the rear side substrate 4 may be made of fiber reinforced plastic (FRP). In particular, FRP may be used for applications that require impact resistance and weight saving. As FRP, glass fiber reinforced plastic (GFRP), carbon fiber reinforced plastic (CFRP), aramid fiber reinforced plastic (AFRP), or the like may be used. Examples of a resin component contained in FRP include polyester, phenolic resin, and epoxy resin.

The wiring member 5 electrically connects the two solar cells 2, that are adjacent to each other in the direction X, in series. In an example illustrated in FIG. 1, in the two solar cells 2 that are adjacent to each other in the direction X, the wiring member 5 electrically connects an electrode on a light receiving surface side of one solar cell 2 and an electrode on a rear surface side of the other solar cell 2. The wiring member 5 is attached to each electrode using adhesive or the like. The wiring member 5 may be formed by, for example, a thin plate-shaped copper foil and solder plated on a front surface of the copper foil, but may be any other conductor.

The sealing member 6 is filled between the front side substrate 3 and the rear side substrate 4 so that the plurality of solar cells 2 are sealed between the front side substrate 3 and the rear side substrate 4. The sealing member 6 includes a front encapsulant 6a and a rear encapsulant 6b. The front encapsulant 6a is arranged between the front side substrate 3 and the solar cells 2, whereas the rear encapsulant 6b is arranged between the solar cells 2 and the rear side substrate 4. The front encapsulant 6a is made of a material having excellent transparency, and the rear encapsulant 6b is comprised of a transparent or colored encapsulant. The front encapsulant 6a may be comprised of a transparent encapsulant and the rear encapsulant 6b may be comprised of a white encapsulant that efficiently reflects light. The sealing member 6 may be configured to include the front encapsulant 6a having excellent transparency and the rear encapsulant 6b having an excellent property of reflecting light, thereby improving the light utilization efficiency.

The front encapsulant 6a and the rear encapsulant 6b are bonded and stacked by lamination that is performed at a temperature about 100 to 200° C., for example. For example, the front encapsulant 6a is stacked on the front side substrate 3, the solar cells 2 and the wiring members 5 are placed thereon, and then the rear encapsulant 6b and the rear side substrate 4 are stacked thereon. The front side substrate 3, the front encapsulant 6a, the solar cells 2, the wiring members 5, the rear encapsulant 6b, and the rear side substrate 4 are heated in such a state and pressed into integration. Note that the rear encapsulant 6b, the solar cells 2 and the wiring members 5, the front encapsulant 6a, and the front side substrate 3 may be stacked on the rear side substrate 4, and heated and pressed. The rear encapsulant 6b is made of a material satisfying at least one of conditions of having a hardness higher than that of the front encapsulant 6a and of having fluidity lower than that of the front encapsulant 6a at a temperature at which the lamination is performed, for example. The front encapsulant 6a may be made of, for example, an ethylene-vinyl acetate copolymer or polyolefin, but is not limited thereto. In addition, the rear encapsulant 6b may be made of, for example, an ethylene-vinyl acetate copolymer or polyolefin, but is not limited thereto. The front encapsulant 6a and the rear encapsulant 6b may be made of the same material. In addition, the frame 7 is made of a hard resin material or the like, and is arranged to surround the periphery of the sealing member 6 in plan view. The frame 7 may be made of a metal material such as aluminum.

Referring again to FIG. 1, the solar cell module 1 includes a first solar cell part 10 and a second solar cell part 20. The first solar cell part 10 and the second solar cell part 20 have the same structure, and are substantially plane symmetrical with respect to a plane vertically dividing the solar cell module 1 into two equal parts, to thereby divide the solar cell module 1 into two equal parts in the direction X. Since the first solar cell part 10 and the second solar cell part 20 have the same structure, the structure of the first solar cell part 10 is described and the description of the second solar cell part 20 is omitted.

In the example illustrated in FIG. 1, the first solar cell part 10 includes four solar cell strings 11, and each solar cell string 11 includes a plurality of solar cells 2 that are arranged on the same straight line along the direction X, and a plurality of wiring members 5. In other words, the plurality of solar cells 2 and the plurality of wiring members 5 that connect the plurality of solar cells 2 in series form the solar cell string 11. In the example illustrated in FIG. 1, regarding the first solar cell part 10, the two solar cells 2 at one end in the direction X in the respective two solar cell strings 11 that are adjacent to each other in the direction Y are connected to each other in series through a relay wiring 40, so that all of the solar cells 2 included in the first solar cell part 10 are connected in series. As a result, for example, in a sheet surface of FIG. 1, a solar cell 2a that is disposed on the uppermost side in the direction X and the rightmost side in the direction Y is disposed on the highest potential side, and a solar cell 2b that is disposed on the uppermost side in the direction X and the leftmost side in the direction Y is disposed on the lowest potential side.

Referring again to FIG. 2, a high-potential side first external wire 71 having higher potential out of a pair of first external wires 71 and 72 protruding from the first terminal box 60 is electrically connected to the solar cell 2a on the highest potential side. In addition, a low-potential side first external wire 72 having lower potential out of the pair of first external wires 71 and 72 protruding from the first terminal box 60 is electrically connected to the solar cell 2b on the lowest potential side. Two first bypass diodes are accommodated in the first terminal box 60. One first bypass diode is connected between a high-potential side node of the solar cell 2a having the highest potential and a low-potential side node of a solar cell 2c having the lowest potential in a solar cell string 11b positioned second from the left in FIG. 2. The other first bypass diode is connected between a low-potential side node of the solar cell 2b having the lowest potential and a high-potential side node of a solar cell 2d having the highest potential in a solar cell string 11c positioned third from the left in FIG. 2.

Furthermore, in the solar cell module 1 of the present disclosure, the first solar cell part 10 and the second solar cell part 20 are electrically connected to each other. More specifically, referring again to FIG. 1, a lowest potential portion 14 in a solar cell string 11a having the highest potential in the first solar cell part 10 and a lowest potential portion 24 in a solar cell string 21a having the highest potential in the second solar cell part 20 are electrically connected to each other. In addition, a highest potential portion 15 in a solar cell string 11d having the lowest potential in the first solar cell part 10 and a highest potential portion 25 in a solar cell string 21d having the lowest potential in the second solar cell part 20 are electrically connected to each other.

The solar cell module 1 of the present embodiment includes the first solar cell part 10 and the second solar cell part 20. The first solar cell part 10 includes one or more first solar cell subgroups. When the first solar cell part 10 includes two or more first solar cell subgroups, the two or more first solar cell subgroups are electrically connected in series. In such a case, the two first solar cell subgroups that are adjacent to each other are electrically connected in series through a wiring member between the first subgroups. The first solar cell subgroup includes the two solar cell strings 11 that are electrically connected in series. The second solar cell part 20 includes one or more second solar cell subgroups. When the second solar cell part 20 includes two or more second solar cell subgroups, the two or more second solar cell subgroups are electrically connected in series. In such a case, the two second solar cell subgroups that are adjacent to each other are electrically connected in series through a wiring member between the second subgroups. The second solar cell subgroup includes the two solar cell strings 11 that are electrically connected in series.

Here, a positive terminal of the first solar cell part 10 and a positive terminal of the second solar cell part 20 may be electrically connected through a positive terminal side wiring member in the solar cell module 1. In addition, a negative terminal of the first solar cell part 10 and a negative terminal of the second solar cell part 20 may be electrically connected through a negative terminal side wiring member in the solar cell module 1. In such a case, one external wire out of the pair of external wires for supplying output to the outside of the solar cell module 1 is electrically connected to the positive terminal side wiring member, and the other external wire out of the pair of external wires is connected to the negative terminal side wiring member.

The solar cell string 11 includes a plurality of solar cells 2 that are electrically connected in series. For example, the solar cell string 11 includes a plurality of solar cells 2 that are electrically connected in series through a plurality of wiring members 5. In the example illustrated in FIG. 1, in the two solar cells 2 that are adjacent to each other included in the solar cell string 11, the wiring member 5 electrically connects the electrode on the light receiving surface side of one solar cell 2 and the electrode on the rear surface side of the other solar cell 2.

The positive terminal of one solar cell string 11 included in the first solar cell subgroup, the negative terminal of the other solar cell string 11 included in the first solar cell subgroup, the positive terminal of one solar cell string 11 included in the second solar cell subgroup, and the negative terminal of the other solar cell string 11 included in the second solar cell subgroup are electrically connected to one another.

In the example illustrated in FIG. 1, the electrode on the light receiving surface side of the solar cell 2 on a positive terminal side of one solar cell string 11 included in the first solar cell subgroup and the electrode on the light receiving surface side of the solar cell 2 on the positive terminal side of one solar cell string 11 included in the second solar cell subgroup are electrically connected through one connecting wiring member. In addition, the electrode on the rear surface side of the solar cell 2 on the negative terminal side of the other solar cell string 11 included in the first solar cell subgroup and the electrode on the rear surface side of the solar cell 2 on the negative terminal side of the other solar cell string 11 included in the second solar cell subgroup are electrically connected through the other connection wiring member. Furthermore, the one connection wiring member and the other connection wiring member are electrically connected through a third wire 52. As described later, a cross-sectional area of the third wire 52 may be larger than that of the wiring member 5. The cross-sectional area of the third wire 52 may be larger than that of a wiring member between the first and second subgroups. In addition, the cross-sectional area of the third wire 52 may be larger than that of each of the positive terminal side wiring member and the negative terminal side wiring member.

The first solar cell subgroup is connected in parallel to one bypass diode or a plurality of bypass diodes connected in series. The second solar cell subgroup is connected in parallel to one bypass diode or a plurality of bypass diodes connected in series. For example, the negative terminal of one solar cell string 11 included in the first solar cell subgroup and the positive terminal of the other solar cell string 11 included in the first solar cell subgroup are connected through one bypass diode or a plurality of bypass diodes connected in series. The negative terminal of one solar cell string 11 included in the second solar cell subgroup and the positive terminal of the other solar cell string 11 included in the second solar cell subgroup are connected through one bypass diode or a plurality of bypass diodes connected in series.

In the example illustrated in FIG. 1, the electrode on the rear surface side of the solar cell 2 on the negative terminal side of one solar cell string 11 included in the first solar cell subgroup and the electrode on the light receiving surface side of the solar cell 2 on the positive terminal side of the other solar cell string 11 included in the first solar cell subgroup are connected through one bypass diode or a plurality of bypass diodes connected in series. The electrode on the rear surface side of the solar cell 2 on the negative terminal side of one solar cell string 11 included in the second solar cell subgroup and the electrode on the light receiving surface side of the solar cell 2 on the positive terminal side of the other solar cell string 11 included in the second solar cell subgroup are connected through one bypass diode or a plurality of bypass diodes connected in series.

The solar cell module 1 of the present embodiment includes the first solar cell subgroup in which the two first solar cell strings are electrically connected in series, the second solar cell subgroup in which the two second solar cell strings are electrically connected in series, a first bypass diode part including one or more first bypass diodes to be electrically connected in parallel to the first solar cell subgroup, and a second bypass diode part including one or more second bypass diodes to be electrically connected in parallel to the second solar cell subgroup, wherein the positive terminal of one first solar cell string out of the two first solar cell strings, the negative terminal of the other first solar cell string out of the two first solar cell string, the positive terminal of one second solar cell string out of the two solar cell strings, and the negative terminal of the other second solar cell string out of the two solar cell strings are electrically connected to one another.

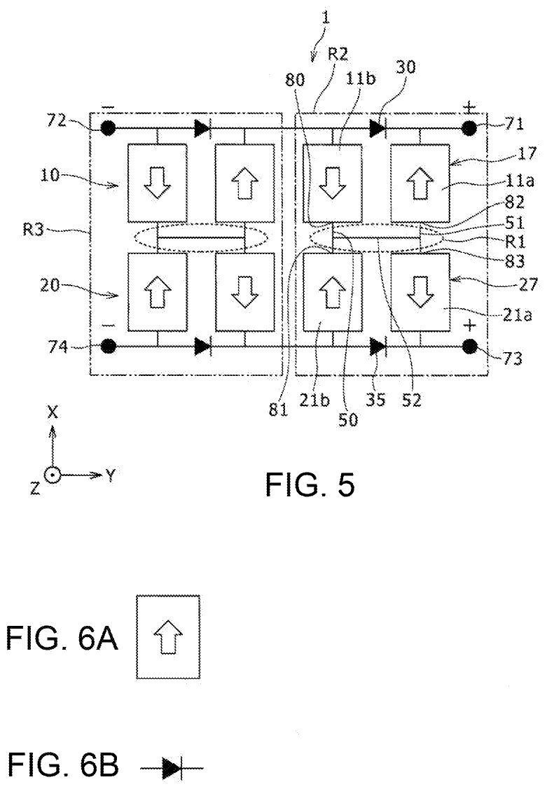

Next, the electric connection between the first solar cell part 10 and the second solar cell part 20 will be described in detail. FIG. 5 illustrates an equivalent circuit of FIG. 1 representing the solar cell module 1 using simplified diagrams. Note that in FIG. 5, the simplified diagram illustrated in FIG. 6A in which an arrow is drawn in a rectangle illustrates a solar cell string, and a direction of the arrow indicates a high potential direction. A diode illustrated in FIG. 6B is a bypass diode. Note that the simplified diagram illustrated in FIG. 6A needs to represent a series of the solar cell strings so that FIG. 5 can illustrate an equivalent circuit of FIG. 1, but in the technique of the present disclosure, the simplified diagram illustrated in FIG. 6A may illustrate a structure in which a plurality of solar cell strings are connected to one another in parallel.

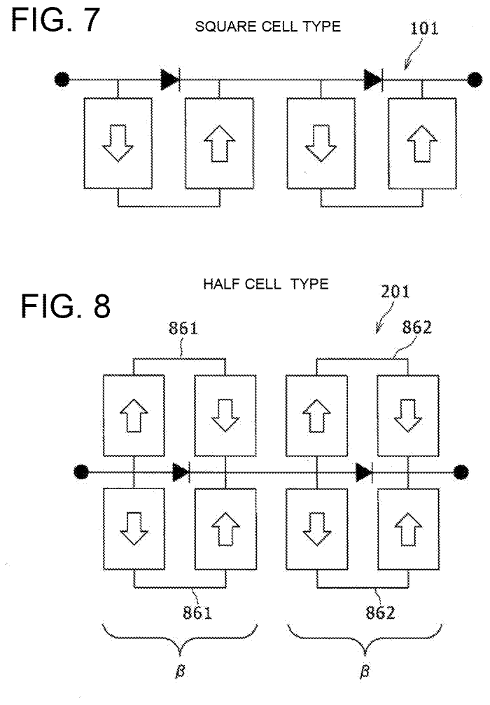

Two solar cell modules 101 of a known square cell type illustrated in FIG. 7 are prepared, and the solar cell module 1 has a structure in which the two solar cell modules 101 thus prepared are arranged in a vertically symmetrical manner, and one solar cell module 101 and the other solar cell module 101 are electrically connected, as illustrated in FIG. 5.

More specifically, the first solar cell part 10 includes a first solar cell subgroup 17 including two first solar cell strings 11a and 11b connected in series, and each of the first solar cell strings 11a and 11 b includes a plurality of solar cells 2 connected in series (see FIG. 1). In addition, the second solar cell part 20 includes a second solar cell subgroup 27 including two second solar cell strings 21a and 21b connected in series, and each of the second solar cell strings 21a and 21b includes a plurality of solar cells 2 connected in series.

In addition, the first solar cell part 10 includes a first bypass diode 30 connected in parallel to the first solar cell subgroup 17, and the second solar cell part 20 includes a second bypass diode 35 connected in parallel to the second solar cell subgroup 27. The first bypass diode 30 forms the first bypass diode part, and the second bypass diode 35 forms the second bypass diode part. The first solar cell part 10 includes a pair of first external wires 71 and 72 that are electrically connected to the first solar cell subgroup 17 and are configured to supply electric power to the outside, and the second solar cell part 20 includes a pair of second external wires 73 and 74 that are electrically connected to the second solar cell subgroup 27 and are configured to supply electric power to the outside.

As indicated a region R1 enclosed by a dotted line in FIG. 5, a first portion 80 having the highest potential in the low-potential side first solar cell string 11b having lower potential out of the two first solar cell strings 11a and 11b, is electrically connected to a second portion 81 having the highest potential in the low-potential side second solar cell string 21b having lower potential out of the two second solar cell strings 21a and 21b. Note that the structure in a region R2 enclosed by a one-dot chain line which is positioned on a right side of FIG. 5 has been described, but a region R3 enclosed by a two-dot chain line which is positioned on a left side of FIG. 5 has the same structure as the region R2 enclosed by the one-dot chain line.

In the conventional solar cell module, the two solar cell modules 101 of a square cell type illustrated in FIG. 7 are arranged independently of each other even when being used, so that the two solar cell modules 101 are not electrically connected to each other. The solar cell module 1 of the present disclosure is quite different from that in the conventional technique in that the first solar cell part 10 and the second solar cell part 20 are electrically connected to each other in the structure in the region R1.

The structure in the region R1 will be described in more detail. The solar cell module 1 includes a first wire 50 for electrically connecting the first portion 80 and the second portion 81. The solar cell module 1 further includes a second wire 51 for electrically connecting a third portion 82 and a fourth portion 83, the third portion 82 having the lowest potential in the high-potential side first solar cell string 11a having higher potential out of the two first solar cell strings 11a and 11b, the fourth portion 83 having the lowest potential in the high-potential side second solar cell string 21a having higher potential out of the two second solar cell strings 21a and 21b. The solar cell module 1 further include the third wire 52 for electrically connecting the first wire 50 and the second wire 51.

As illustrated in FIG. 3, the cross-sectional area of the third wire 52 is larger than that of the wiring member 5 for electrically connecting between the solar cells 2 that are adjacent to each other in the first solar cell strings 11a and 11b. As illustrated in FIG. 5, the first solar cell part 10 and the second solar cell part 20 have the same structure, and the first solar cell part 10 and the second solar cell part 20 are arranged in a symmetrical manner in an up-down direction of the direction X. Accordingly, a combined current of a current generated in the first solar cell part 10 and a current generated in the second solar cell part 20 flows in the third wire 52. Therefore, in the third wire 52, the joule heat proportional to I²R, where “I” represents the current and “R” represents the resistance in the third wire 52, increases, so that the energy loss tends to increase. When the cross-sectional area of the third wire 52 is made larger than that of the wiring member 5, in particular, four times or more the cross-sectional area of the wiring member 5, the joule heat generated in the third wire 52 can be suppressed to the same extent as the joule heat generated in the wiring member 5, resulting in a reduction in the energy loss. Note that the cross-sectional area of the third wire 52 may be larger than that of each of the first wire 50 and the second wire 51.

Next, the effect of the solar cell module of the present disclosure will be described with reference to the results of a simulation.

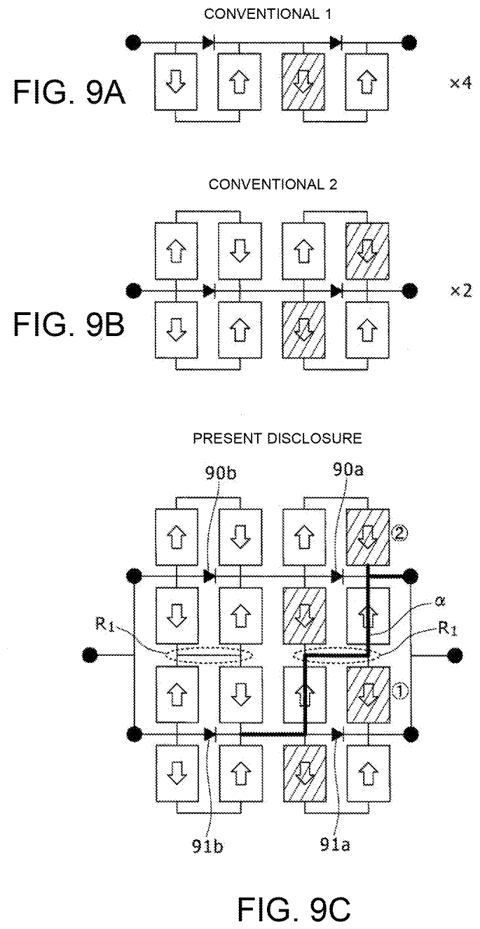

The present inventors have calculated a module output, a current flowing in a particular solar cell string in a state in which hardly any light is incident on the solar cell string, and a current flowing in the bypass diode by simulation, in each of the three solar cell modules illustrated in respective FIG. 9A, FIG. 9B, and FIG. 9C.

More specifically, a solar cell module of a square cell type illustrated in FIG. 9A is used as a first solar cell module of conventional 1. A solar cell module of a half cell type illustrated in FIG. 9B is used as a second solar cell module of conventional 2. As a third solar cell module of the present disclosure, a solar cell module illustrated in FIG. 9C is used in which two solar cell modules of a half cell type are arranged in a symmetrical manner in the direction X, and four solar cell strings facing one another and corresponding to one another in one solar cell module and the other solar cell module are electrically connected in the same connection structure as the electrical connection structure in the region R1 in FIG. 5.

Note that the solar cell module of the present disclosure illustrated in FIG. 9C includes two first bypass diodes 90a and 90b and two second bypass diodes 91a and 91b. The low potential side of the first bypass diode 90a is electrically connected to the high potential side of the first bypass diode 90b. In addition, the low potential side of the second bypass diode 91a is electrically connected to the high potential side of the second bypass diode 91b. Furthermore, in the solar cell module of the present disclosure, the electric connection structure in the region R1 in FIG. 5 is provided at two places. In the solar cell module of the present disclosure illustrated in FIG. 9C, two high-potential side external wires are electrically connected to form only one high-potential side external wire, and two low-potential side external wires are electrically connected to form only one low-potential side external wire.

The simulation is performed under the following conditions. That is, regarding each of the hatched solar cell strings in the solar cell modules illustrated in respective FIG. 9A, FIG. 9B, and FIG. 9C, a condition is assumed in which at least part is covered with light-shielding objects such as fallen leaves. A module output (Output), a current (Current) flowing in the hatched solar cell string, and a current (Current) flowing in the bypass diode connected in parallel to the solar cell subgroup including the hatched solar cell string are measured, when the illuminance of incident light (I-photo) is reduced from 6, which is the illuminance of light when the maximum current flows in the hatched solar cell string to which light-shielding objects are not attached. Note that the illuminance of light incident on the solar cell string which is not the hatched solar cell string is fixed at 6.

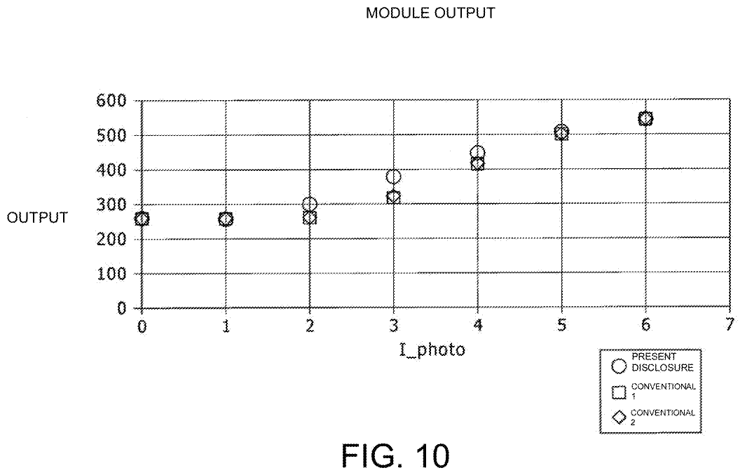

FIG. 10 is a graph showing a module output (Output) which is provided by the simulation. The output of the conventional solar cell module 1 is obtained by quadrupling the output result of the solar cell module illustrated in FIG. 9A. The output of the conventional solar cell module 2 is obtained by doubling the output result of the solar cell module illustrated in FIG. 9B. The output of the solar cell module of the present disclosure is the output result itself of the solar cell module illustrated in FIG. 9C. This is a measure to adjust the number of solar cell strings in each of the solar cell modules illustrated in FIGS. 9A, 9B, and 9C respectively, the number being included in each condition, to compare the outputs of the solar cell modules illustrated in respective FIGS. 9A, 9B, and 9C.

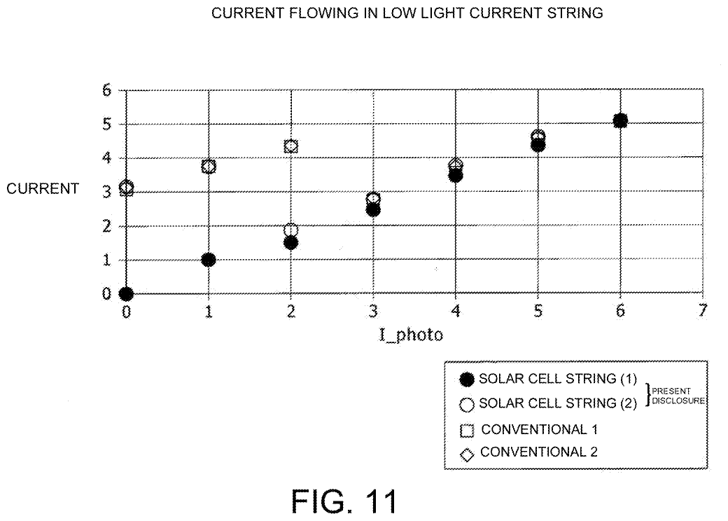

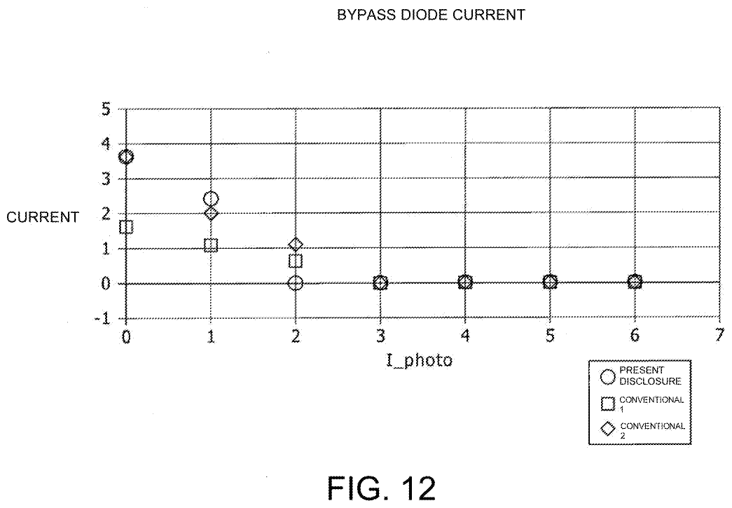

FIG. 11 is a graph showing a current (Current) flowing in the hatched solar cell string which is provided by the simulation. Here, in the solar cell module of the present disclosure illustrated in FIG. 9C, a current flowing in a solar cell string (1) which is positioned inside among the hatched solar cell strings is indicated by a black circle, and a current flowing in a solar cell string (2) which is position outside among the hatched solar cell strings is indicated by a white circle. In addition, FIG. 12 is a graph showing a current (Current) flowing in the bypass diode connected in parallel to the solar cell subgroup including the hatched solar cell string which is provided by the simulation.

According to the simulation result shown in FIG. 10, especially in the case where the illuminance of light is 2 to 4, the output of the solar cell module of the present disclosure is higher than that of each of the conventional solar cell module 1 and the conventional solar cell module 2. The result shows that when the illuminance of light is 5, the output of the solar cell module of the present disclosure is higher than that of the solar cell module of conventional 1 by 2%, and is higher than that of the solar cell module of conventional 2 by 1%. The result shows that when the illuminance of light is 4, the output of the solar cell module of the present disclosure is higher than that of the solar cell module of conventional 1 by 8%, and is higher than that of solar cell module of conventional 2 by 7%. The result shows that when the illuminance of light is 3, the output of the solar cell module of the present disclosure is higher than that of the solar cell module of conventional 1 by 20%, and is higher than that of solar cell module of conventional 2 by 18%. The result shows that when the illuminance of light is 2, the output of the solar cell module of the present disclosure is higher than that of the solar cell module of conventional 1 by 17%, and is higher than that of solar cell module of conventional 2 by 17%. Accordingly, using the solar cell module of the present disclosure helps to maintain a high output, even when the solar cell string included in the solar cell module is covered with light-shielding objects.

Furthermore, the number of bypass diodes of the solar cell module of the present disclosure illustrated in FIG. 9C is four. The number of bypass diodes of the solar cell module of conventional 2 illustrated in FIG. 9B is two. The number of bypass diodes of the solar cell module of conventional 1 illustrated in FIG. 9A is two. In consideration of measures to adjust the number of the solar cell strings included in each condition, the number of bypass diodes included in the condition of the solar cell module of conventional 2 is four, and the number of bypass diodes included in the condition of the solar cell module of conventional 1 is eight. Accordingly, according to the present disclosure, the solar cell module can be provided which can easily maintain a high output with a simple configuration and at a low cost, without increasing the number of bypass diodes.

Furthermore, according to the simulation result shown in FIG. 11, in the case where the illuminance of light is 2, the current flowing in each of the hatched solar cell strings in the solar cell modules of conventional 1 and conventional 2 is considerably higher than the current flowing in the hatched solar cell string in the solar cell module of the present disclosure. That is, in the solar cell modules of conventional 1 and conventional 2, excessive current flows in the hatched solar cell string in a situation where an amount of current to be generated should be reduced because hardly any light is incident on the hatched solar cell.

This means that an amount of current flowing from the surroundings is increased. In the case where the excessive current has flowed in the solar cell string in which the hardly ant current flows because the solar cell string is covered with the light-shielding objects, the excessive heat is generated in the solar cell string, thereby causing excessive energy loss. Furthermore, when such a situation occurs, the solar cells in the solar cell module are easily subjected to thermal damage, and the solar cell module may be damaged. Accordingly, according to the solar cell module of the present disclosure, in the state in which hardly any light is incident on any of the solar cell strings due to the influence of the light-shielding objects, the energy loss can be suppressed, and the thermal damage to the solar cells and the solar cell module can be also suppressed.

According to the simulation result shown in FIG. 12, when the illuminance of light is 2, no current flows in the bypass diodes, only in the solar cell module of the present disclosure. The current flows in the bypass diodes in avoiding an inconvenient situation such as damage to the solar cells. Therefore, according to the solar cell module of the present disclosure, it is possible to easily suppress the occurrence of such an inconvenient situation.

The present inventors presume that the reason why the solar cell module of the present disclosure can attain the excellent effect in the simulation results shown in FIG. 10 to FIG. 12 is as follows. That is, when hardly any light is incident on some solar cell strings among the plurality of solar cell strings in the situations illustrated in FIG. 9A, FIG. 9B, and FIG. 9C, in the solar cell modules of conventional 1 and conventional 2, the current must necessarily flow in the hatched solar cell strings when flowing between the external wires without flowing in the bypass diodes. In contrast, in the case of the solar cell module of the present application, the electrical connection structure exists in the region R1. Accordingly, when the current flows between the external wires without flowing in the bypass diodes, the current flows in a path a indicated by a bold line, whereby the current can flow between the external wires without flowing through the hatched solar cell strings. Therefore, since the current can be diverted, the significant effect shown in FIG. 10 to FIG. 12 can be attained.

The same effect can be achieved not only on the structure of the solar cell module of the present disclosure illustrated in FIG. 9C but also on the solar cell module of the present disclosure having a characteristic connection structure between the first solar cell subgroup and the second solar cell subgroup as illustrated in the region R1 enclosed by a dotted line in FIG. 5, for example. In the solar cell module of the present disclosure, this characteristic connection structure enables diversion of current. Therefore, when hardly any light is incident on some solar cell strings, the solar cell module of the present disclosure can be provided which can easily maintain a high output with a simple configuration and at a low cost, compared with the conventional solar cell modules. Since this characteristic connection structure enables diversion of current, the energy loss can be suppressed, and the thermal damage to the solar cells and the solar cell module can also be suppressed, compared with the conventional solar cell modules.

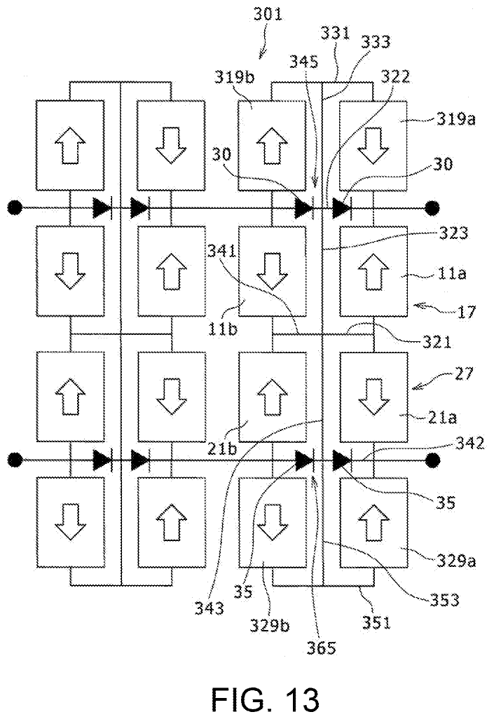

FIG. 13 is a diagram illustrating a solar cell module 301 of a modification using simplified diagrams illustrated in FIG. 6A. In the solar cell module 301, a first bypass diode part 345 connected in parallel to a first solar cell subgroup 17 including two first solar cell strings 11a and 11b includes two first bypass diodes 30 and 30 connected in series. In addition, the solar cell module 301 includes two third solar cell strings 319a and 319b that are connected in parallel to the first bypass diode part 345 and are connected in series. Moreover, the solar cell module 301 includes a first divided wire 323 for electrically connecting a first string connection wire 321 and a first diode connection wiring 322, the first string connection wire 321 electrically connecting the two first solar cell strings 11a and 11 b, the first diode connection wire 322 electrically connecting the two first bypass diodes 30 and 30. Furthermore, the solar cell module 301 includes a third divided wire 333 for electrically connecting the first diode connection wiring 322 and a third string connection wire 331 electrically connecting the two third solar cell strings 319a and 319b.

In the solar cell module 301, a second bypass diode part 365 connected in parallel to a second solar cell subgroup 27 including two second solar cell strings 21a and 21b includes two second bypass diodes 35 and 35 connected in series. In addition, the solar cell module 301 includes two fourth solar cell strings 329a and 329b that are connected in parallel to the second bypass diode part 365 and are connected in series. Moreover, the solar cell module 301 includes a second divided wire 343 for electrically connecting a second string connection wire 341 and a second diode connection wire 342, the second string connection wire 341 electrically connecting the two second solar cell strings 21a and 21b, the second diode connection wire 342 electrically connecting the two second bypass diodes 35 and 35. The first string connection wire 321 matches the second string connection wire 341. Furthermore, the solar cell module 301 includes a fourth divided wire 353 for electrically connecting the second diode connection wire 342 and a fourth string connection wire 351 electrically connecting the two fourth solar cell strings 329a and 329b.

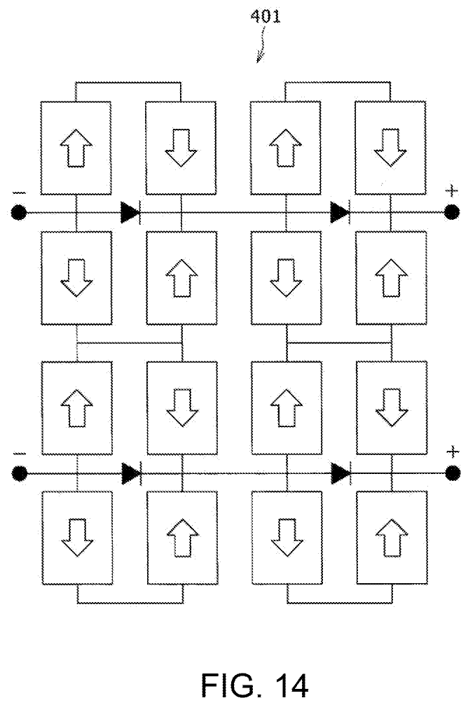

In this solar cell module 301, the number of bypass diodes is increased, compared with a solar cell module 401 illustrated in FIG. 14 which is the same as in FIG. 9C except that no external wires are connected. Therefore, reduction in the electric power supply due to the influence of the light-shielding objects can be reduced.

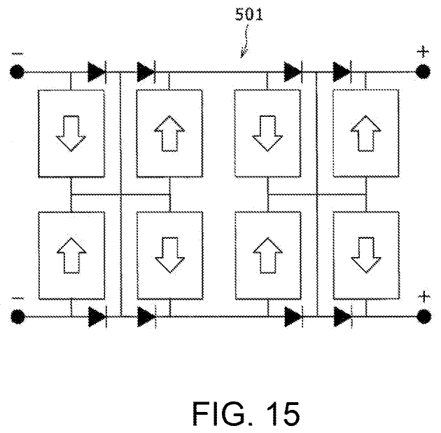

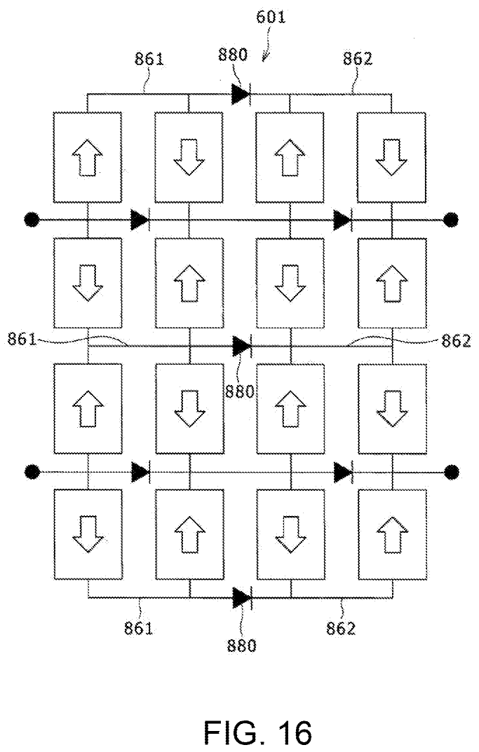

FIG. 15 is a diagram illustrating a solar cell module 501 of other modification using simplified diagrams illustrated in FIG. 6A. As in this solar cell module 501, the third solar cell strings 319a and 319b and the fourth solar cell strings 329a and 329b may be omitted, compared with the solar cell module 301 illustrated in FIG. 13. In addition, the solar cell module 601 illustrated in FIG. 16 may be configured to be different from the solar cell module 401 illustrated in FIG. 14 only in that in a half cell structure (see FIG. 8) in which the same substructures β are repeated two times, one string connection wire 861 for electrically connecting two solar cell strings connected in series in one substructure β and the other string connection wire 862 for electrically connecting two solar cell strings connected in series in the other substructure β are electrically connected through a bypass diode 880.

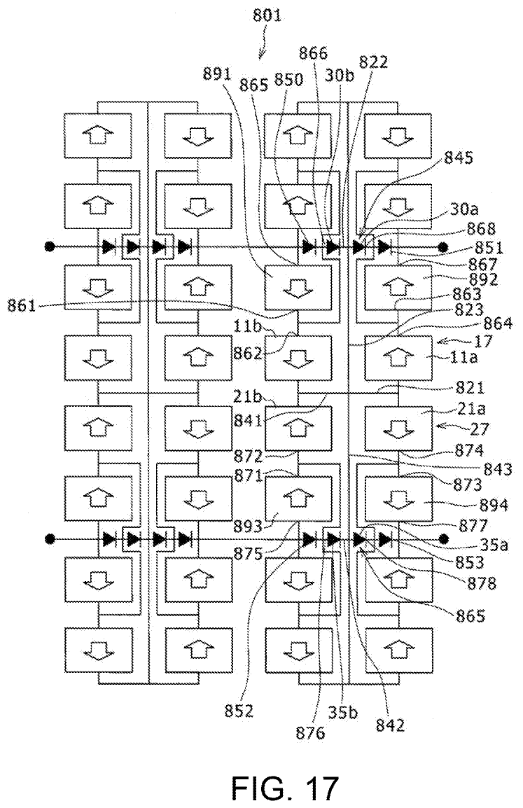

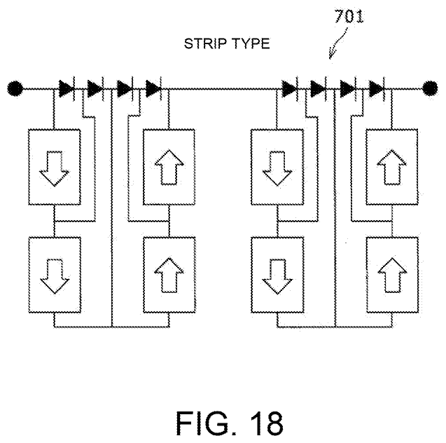

As illustrated in FIG. 17, the technical idea of the present disclosure may be applied to a solar cell module 701 of a known strip type illustrated in FIG. 18. More specifically, in a solar cell module 801 illustrated in FIG. 17, a first bypass diode part 845 connected in parallel to the first solar cell subgroup 17 including the two first solar cell strings 11a and 11b includes two first bypass diodes 30a and 30b connected in series. In addition, the solar cell module 801 includes a first diode connection wiring 822 for electrically connecting the two first bypass diodes 30a and 30b, a first string connection wiring 821 for electrically connecting the two first solar cell strings 11a and 11b, and a first divided wire 823 for electrically connecting the first diode connection wire 822 and the first string connection wire 821.

The solar cell module 801 includes a third solar cell string 891 in which a fifth portion 861 having the highest potential is electrically connected to a sixth portion 862 having the lowest potential in the low-potential side first solar cell string 11b having lower potential out of the two first solar cell strings 11a and 11b. In addition, the solar cell module 801 includes a fourth solar cell string 892 in which a seventh portion 863 having the lowest potential is electrically connected to an eighth portion 864 having the highest potential in the high-potential side first solar cell string 11a having higher potential out of the two first solar cell strings 11a and 11b. Furthermore, the solar cell module 801 includes a third bypass diode 850 in which a low potential side is electrically connected to a ninth portion 865 having the lowest potential in the third solar cell string 891, whereas a high potential side is electrically connected to a tenth portion 866 on a low potential side of the low-potential side first bypass diode 30b having lower potential out of the two first bypass diodes 30a and 30b.

The solar cell module 801 includes a fourth bypass diode 851 in which a high potential side is electrically connected to an eleventh portion 867 having the highest potential in the fourth solar cell string 892, whereas a low potential side is electrically connected to a twelfth portion 868 on a high potential side of the high-potential side first bypass diode 30a having higher potential out of the two first bypass diodes 30a and 30b.

In the solar cell module 801, a second bypass diode part 865 connected in parallel to the second solar cell subgroup 27 including the two second solar cell strings 21a and 21b includes two second bypass diodes 35a and 35b connected in series. In addition, the solar cell module 801 includes a second diode connection wire 842 for electrically connecting the two second bypass diodes 35a and 35b, a second string connection wire 841 for electrically connecting the two second solar cell strings 21a and 21b, and a second divided wire 843 for electrically connecting the second diode connection wiring 842 and the second string connection wire 841. The first string connection wire 821 matches the second string connection wire 841.

The solar cell module 801 includes a fifth solar cell string 893 in which a thirteenth portion 871 having the highest potential is electrically connected to a fourteenth portion 872 having the lowest potential in the low-potential side second solar cell string 21a having lower potential out of the two second solar cell strings 21a and 21b. In addition, the solar cell module 801 includes a sixth solar cell string 894 in which a fifteenth portion 873 having the lowest potential is electrically connected to a sixteenth portion 874 having the highest potential in the high-potential side second solar cell string 21a having higher potential out of the two second solar cell strings 21a and 21b.

The solar cell module 801 includes a fifth bypass diode 852 in which a low potential side is electrically connected to a seventeenth portion 875 having the lowest potential in the fifth solar cell string 893, whereas a high potential side is electrically connected to an eighteenth portion 876 on a low potential side of the low-potential side second bypass diode 35b having lower potential out of the two second bypass diodes 35a and 35b. In addition, the solar cell module 801 includes a sixth bypass diode 853 in which a high potential side is electrically connected to a nineteenth portion 877 having the highest potential in the sixth solar cell string 894, whereas a low potential side is electrically connected to a twentieth portion 878 on a high potential side of the high-potential side second bypass diode 35a having higher potential out of the two second bypass diodes 35a and 35b. In this solar cell module 801, the bypass diodes 30a, 30b, 35a, 35b, 850, 851, 852, and 853 are added, compared with a solar cell module 301 illustrated in FIG. 13. Therefore, reduction in the electric power supply due to the influence of the light-shielding objects can be further reduced.

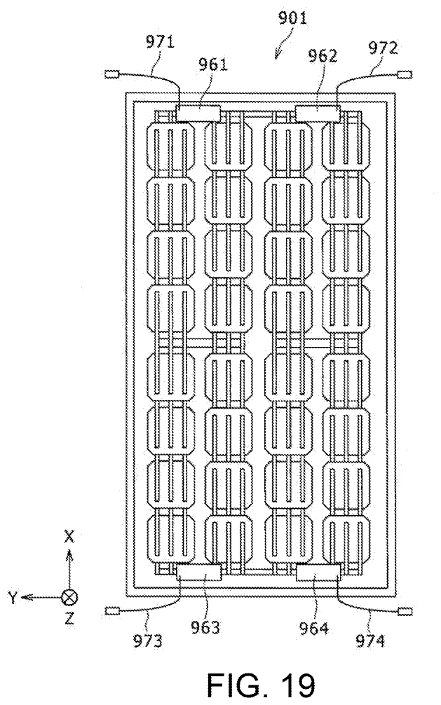

Note that the case has been described where, as illustrated in FIG. 2, the solar cell module 1 includes two terminal boxes 60 and 61, and a pair of external wires 71 and 72 and a pair of external wires 81 and 82 protrude from the terminal boxes 60 and 61, respectively. However, as illustrated in FIG. 19, i.e., a diagram corresponding to FIG. 2 in a solar cell module 901 of another modification, the solar cell module 901 may include four terminal boxes 961, 961, 963, and 964. A pair of terminal boxes 961 and 962 may be arranged at both ends in the direction Y on one side in the direction X, and the other pair of terminal boxes 963 and 964 may be arranged at both ends in the direction Y on the other side in the direction X. External wires 971, 972, 973, and 974 may protrude from the terminal boxes 961, 962, 963, and 964, respectively. Note that in the solar cell module 901, the external wire 971 and the external wire 973 are external wires on the high potential side, and the external wire 972 and the external wire 974 are external wires on the low potential side.

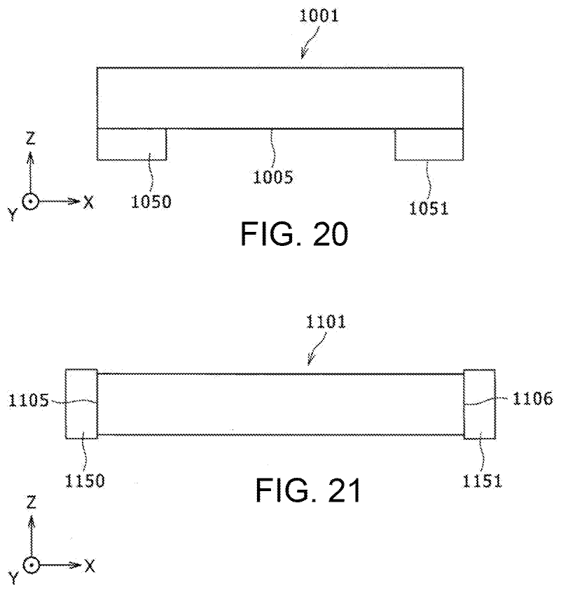

In the context as illustrated in FIG. 20, terminal boxes 1050 and 1051 may be installed at ends in the direction X in a rear surface 1005 of a rear side substrate of a solar cell module 1001. Alternatively, as illustrated in FIG. 21, terminal boxes 1150 and 1151 may be installed on respective side surfaces 1105 and 1106 extending in the direction Y, in a solar cell module 1101. Since in these solar cell modules 1001 and 1101, the terminal boxes 1050, 1051, 1150 and 1151 are arranged at the ends in the direction X, the designability of the solar cell modules 1001 and 1101 can be enhanced compared with the case where the terminal boxes are installed at the center in the direction X, thereby providing the solar cell modules 1001 and 1101 having excellent appearance. Furthermore, when the terminal boxes 1050, 1051, 1150 and 1151 are arranged at the ends, the terminal boxes 1050, 1051, 1150 and 1151 are easily hidden compared with the case where the terminal boxes are installed at the center in the direction X. Accordingly, the solar cell modules 1001 and 1101 of forms illustrated in FIG. 20 and FIG. 21 may be installed on a roof or may be installed at a place exposed to public view, such as on fences.

Next, a solar cell system including a plurality of solar cell modules of the present disclosure will be described. The solar cell module of the present disclosure includes two pairs of external wires for extracting electric power unlike the conventional solar cell module including only a pair of external wires. Therefore, the degree of freedom of the connection of the external wires is enhanced.

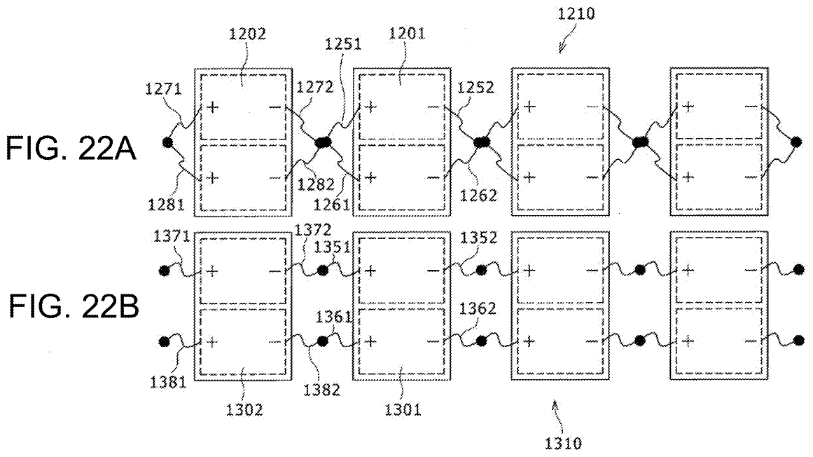

As in a solar cell system 1210 illustrated in FIG. 22A, for example, the solar cell system 1210 includes a first solar cell module 1201 and a second solar cell module 1202. A high-potential side first external wire 1251 on the high potential side out of a pair of first external wires 1251 and 1252 in the first solar cell module 1201 and a high-potential side second external wire 1261 on the high potential side out of a pair of second external wires 1261 and 1262 in the first solar cell module 1201 may be electrically connected to each other. In addition, a low-potential side first external wire 1272 on the low potential side out of a pair of first external wires 1271 and 1272 in the second solar cell module 1202 and a low-potential side second external wire 1282 on the low potential side out of a pair of second external wires 1281 and 1282 in the second solar cell module 1202 may be electrically connected to each other. Furthermore, the high-potential side first external wire 1251 of the first solar cell module 1201 and the low-potential side first external wire 1272 of the second solar cell module 1202 may be electrically connected to each other.

Alternatively, as in a solar cell system 1310 illustrated in FIG. 22B, the solar cell system 1310 includes a first solar cell module 1301 and a second solar cell module 1302. A high-potential side first external wire 1351 on the high potential side out of a pair of first external wires 1351 and 1352 in the first solar cell module 1301 and a low-potential side first external wire 1372 on the low potential side out of a pair of first external wires 1371 and 1372 in the second solar cell module 1302 may be electrically connected to each other. In addition, a high-potential side second external wire 1361 on the high potential side out of a pair of second external wires 1361 and 1362 in the first solar cell module 1301 and a low-potential side second external wire 1382 on the low potential side out of a pair of second external wires 1381 and 1382 in the second solar cell module 1302 may be electrically connected to each other.

Note that the solar cell module of the present disclosure may be manufactured by any method, but can be manufactured according to the following procedure, for example. That is, firstly, two types of first and second strings are manufactured, the first and second strings being electrically connected in series and extending in the direction X. Here, in the first string, a front-side electrode of a solar cell at an end and a rear-side electrode of a solar cell adjacent to the solar cell at the end are electrically connected through a wiring member, and this connection is repeated alternately. Note that only a center wiring member electrically connects between the front-side electrode and the front-side electrode or between the rear-side electrode and the rear-side electrode.

In the second string, a rear-side electrode of a solar cell at an end and a front-side electrode of a solar cell adjacent to the solar cell at the end are electrically connected through a wiring member, and this connection is repeated alternately. Note that only a center wiring member electrically connects between the rear-side electrode and the rear-side electrode or between the front-side electrode and the front-side electrode.

Thereafter, the first string extending in the direction X and the second string extending in the direction X are alternately arranged in the direction Y, and the first string and the second string are electrically connected through a bridge wiring member extending in the direction Y. At this time, the wiring member electrically connecting the same poles in the first string and the wiring member electrically connecting the same poles in the second string are electrically connected through the bridge wiring member extending in the direction Y. When the solar cell module is manufactured with this method, the solar cell module can be manufactured efficiently and at a low cost.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell module, comprising:
a first solar cell subgroup including two first solar cell strings connected in series, in which each of the first solar cell strings includes a plurality of solar cells;
a second solar cell subgroup including two second solar cell strings connected in series, in which each of the second solar cell strings includes a plurality of solar cells;
a first bypass diode part that is connected in parallel to the first solar cell subgroup and includes one first bypass diode or a plurality of first bypass diodes connected in series;
a second bypass diode part that is connected in parallel to the second solar cell subgroup and includes one second bypass diode or a plurality of second bypass diodes connected in series;
a pair of first external wires used to supply electric power to outside; and
a pair of second external wires used to supply electric power to the outside,
wherein a first portion having the highest potential in a low-potential side first solar cell string having lower potential out of the two first solar cell strings and a second portion having the highest potential in a low-potential side second solar cell string having lower potential out of the two second solar cell strings are electrically connected to each other.

2. The solar cell module according to claim 1, further comprising:
a first wiring for electrically connecting the first portion and the second portion;
a second wire for electrically connecting a third portion and a fourth portion, the third portion having the lowest potential in a high-potential side first solar cell string having higher potential out of the two first solar cell strings, the fourth portion having the lowest potential in a high-potential side second solar cell string having higher potential out of the two second solar cell strings; and
a third wire for electrically connecting the first wire and the second wire,
wherein a cross-sectional area of the third wire is larger than that of the wire member for electrically connecting between the solar cells that are adjacent to each other in the first solar cell strings.

3. The solar cell module according to claim 1, further comprising:
two third solar cell strings that are connected in parallel to the first bypass diode part and are connected in series; and
two fourth solar cell strings that are connected in parallel to the second bypass diode part and are connected in series.

4. The solar cell module according to claim 3, in which the first bypass diode part includes the two first bypass diodes connected in series and the second bypass diode part includes the two second bypass diodes connected in series, the solar cell module further comprising:
a first divided wire for electrically connecting a first string connection wire and a first diode connection wire, the first string connection wire electrically connecting the two first solar cell strings, the first diode connection wire electrically connecting the two first bypass diodes;
a second divided wiring for electrically connecting a second string connection wire and a second diode connection wire, the second string connection wire electrically connecting the two second solar cell strings, the second diode connection wire electrically connecting the two second bypass diodes;
a third divided wiring for electrically connecting the first diode connection wire and a third string connection wire electrically connecting the two third solar cell strings; and
a fourth divided wire for electrically connecting the second diode connection wire and a fourth string connection wire electrically connecting the two fourth solar cell strings.

5. The solar cell module according to claim 1,
the solar cell module in which the first bypass diode part includes the two first bypass diodes connected in series, comprising:
a first diode connection wire for electrically connecting the two first bypass diodes;
a first string connection wire for electrically connecting the two first solar cell strings;
a first divided wire for electrically connecting the first diode connection wire and the first string connection wire;
a third solar cell string in which a fifth portion having the highest potential is electrically connected to a sixth portion having the lowest potential in a low-potential side first solar cell string having lower potential out of the two first solar cell strings;
a fourth solar cell string in which a seventh portion having the lowest potential is electrically connected to an eighth portion having the highest potential in a high-potential side first solar cell string having higher potential out of the two first solar cell strings;
a third bypass diode in which a low potential side is electrically connected to a ninth portion having the lowest potential in the third solar cell string, whereas a high potential side is electrically connected to a tenth portion on a low potential side of a low-potential side first bypass diode having lower potential out of the two first bypass diodes; and
a fourth bypass diode in which a high potential side is electrically connected to an eleventh portion having the highest potential in the fourth solar cell string, whereas a low potential side is electrically connected to a twelfth portion on a high potential side of a high-potential side first bypass diode having higher potential out of the two first bypass diodes, and
the solar cell module in which the second bypass diode part includes the two second bypass diodes connected in series, comprising:
a second diode connection wire for electrically connecting the two second bypass diodes;
a second string connection wire for electrically connecting the two second solar cell strings;
a second divided wire for electrically connecting the second diode connection wire and the second string connection wire;
a fifth solar cell string in which a thirteenth portion having the highest potential is electrically connected to a fourteenth portion having the lowest potential in a low-potential side second solar cell string having lower potential out of the two second solar cell strings;
a sixth solar cell string in which a fifteenth portion having the lowest potential is electrically connected to a sixteenth portion having the highest potential in a high-potential side second solar cell string having higher potential out of the two second solar cell strings;
a fifth bypass diode in which a low potential side is electrically connected to a seventeenth portion having the lowest potential in the fifth solar cell string, whereas a high potential side is electrically connected to an eighteenth portion on a low potential side of a low-potential side second bypass diode having lower potential out of the two second bypass diodes; and
a sixth bypass diode in which a high potential side is electrically connected to a nineteenth portion having the highest potential in the sixth solar cell string, whereas a low potential side is electrically connected to a twentieth portion on a high potential side of a high-potential side second bypass diode having higher potential out of the two second bypass diodes.

6. A solar power system, comprising:
the first solar cell module according to claim 1; and
the second solar cell module according to claim 1,
wherein a high-potential side first external wire on a high-potential side out of the pair of first external wires in the first solar cell module and a high-potential side second external wire on a high-potential side out of the pair of second external wires in the first solar cell module are electrically connected to each other,
a low-potential side first external wire on a low-potential side out of the pair of first external wires in the second solar cell module and a low-potential side second external wire on a low-potential side out of the pair of second external wires in the second solar cell module are electrically connected to each other, and
the high-potential side first external wire of the first solar cell module and the low-potential side first external wire of the second solar cell module are electrically connected to each other.

7. A solar power system, comprising:
the first solar cell module according to claim 1; and
the second solar cell module according to claim 1,
wherein a high-potential side first external wire on a high-potential side out of the pair of first external wires in the first solar cell module and a low-potential side first external wire on a low-potential side out of the pair of first external wires in the second solar cell module are electrically connected to each other, and
a high-potential side second external wire on a high-potential side out of the pair of second external wires in the first solar cell module and a low-potential side second external wire on a low-potential side out of the pair of second external wires in the second solar cell module are electrically connected to each other.

8. A solar cell module, comprising:
a first solar cell subgroup electrically connecting two first solar cell strings in series;
a second solar cell subgroup electrically connecting two second solar cell strings in series;
a first bypass diode part including one or more first bypass diodes electrically connected in parallel to the first solar cell subgroup; and
a second bypass diode part including one or more second bypass diodes electrically connected in parallel to the second solar cell subgroup,
wherein a positive terminal of one first solar cell string included in the two first solar cell strings, a negative terminal of another first solar cell string included in the two first solar cell strings, a positive terminal of one second solar cell string included in the two second solar cell strings, and a negative terminal of another second solar cell string included in the two second solar cell strings are electrically connected to one another.
